(19) United States
(12) Patent Application Publication
(10) Pub. No.: US 2016/0194781 A1
(43) Pub. Date: Jul. 7, 2016

(54) REACTOR VESSELS FOR AMMONOTHERMAL AND FLUX-BASED GROWTH OF GROUP-III NITRIDE CRYSTALS

(71) Applicant: THE REGENTS OF THE UNIVERSITY OF CALIFORNIA, Oakland, CA (US)

(72) Inventors: Siddha Pimputkar, Santa Barbara, CA (US); Shuji Nakamura, Santa Barbara, CA (US); James S. Speck, Santa Barbara, CA (US)

(73) Assignee: The Regents of the University of California, Oakland, CA (US)

(21) Appl. No.: 14/909,926

(22) PCT Filed: Aug. 29, 2014
(86) PCT No.: PCT/US14/53479

§ 371 Date: Feb. 3, 2016

Related U.S. Application Data
(60) Provisional application No. 61/872,036, filed on Aug. 30, 2013.
(60) Provisional application No. 61/873,961, filed on Sep. 5, 2013.

(51) Int. Cl. C30B 7/10; C30B 29/40; C30B 9/12

(52) U.S. Cl. CPC C30B 7/105; C30B 9/12; C30B 29/403

(57) ABSTRACT

A method and apparatus for growing a Group-III nitride crystal using multiple interconnected reactor vessels to modify growth conditions during the ammonothermal growth of the Group-III nitride crystal, such that, by combining two or more vessels, it is possible to modify the conditions under which the Group-III nitride crystals are grown. In addition, the reactor vessel may use carbon fiber containing materials encapsulating oxide ceramic materials as structural elements to contain the materials for growing the Group-III nitride crystals at pressures or temperatures necessary for growth of the Group-III nitride crystals.

### CROSS REFERENCE TO RELATED APPLICATIONS

This application claims the benefit under 35 U.S.C Section 119(e) of the following co-pending and commonly-assigned applications:

U.S. Provisional Application Ser. No. 61/872,036, filed on Aug. 30, 2013, by Siddha Pimputkar, Shuji Nakamura, and James S. Speck, entitled “USE OF CERAMICS AND COMPOSITE MATERIALS FOR THE GROWTH OF GROUP-III NITRIDE BULK CRYSTALS,” attorneys' docket number 30794.527-US-P1 (2014-116-1); and

U.S. Provisional Application Ser. No. 61/873,961, filed on Sep. 5, 2013, by Siddha Pimputkar, Shuji Nakamura and James S. Speck, entitled “USE OF MULTIPLE INTERCONNECTED VESSELS TO MODIFY GROWTH CONDITIONS FOR AMMONOTHERMAL GALLIUM NITRIDE GROWTH,” attorneys' docket number 30794.529-US-P1 (2014-133-1);

both of which applications are incorporated by reference herein.

This application is related to the following co-pending and commonly-assigned patent applications:

P.C.T. International Application Ser. No. PCT/US2012/046756, filed on Jul. 13, 2012, by Siddha Pimputkar, Shuji Nakamura, and James S. Speck, entitled “GROWING A GROUP-III NITRIDE CRYSTAL USING A FLUX GROWTH AND THEN USING THE GROUP-III NITRIDE CRYSTAL AS A SEED FOR AN AMMONOTHERMAL RE-GROWTH,” attorneys' docket number 30794.419-WO-U1 (2012-020-2), which application claims the benefit under 35 U.S.C. Section 119(e) of U.S. Provisional Application Ser. No. 61/507,170, filed on Jul. 13, 2011, by Siddha Pimputkar and Shuji Nakamura, entitled “USE OF GROUP-III NITRIDE CRYSTALS GROWN USING A FLUX METHOD AS SEEDS FOR AMMONOTHERMAL GROWTH OF A GROUP-III NITRIDE CRYSTAL” attorneys' docket number 30794.419-US-P1 (2012-020-1), and U.S. Provisional Application Ser. No. 61/507,187, filed on Jul. 13, 2011, by Siddha Pimputkar and James S. Speck, entitled “METHOD OF GROWING A BULK GROUP-III NITRIDE CRYSTAL USING A FLUX BASED METHOD THROUGH PREPARING THE FLUX PRIOR TO BRINGING IT IN CONTACT WITH THE GROWING CRYSTAL” attorneys' docket number 30794.421-US-P1 (2012-022);

all of which applications are incorporated by reference herein.

This application is also related to the following co-pending and commonly-assigned applications:

U.S. Provisional Application Ser. No. 61/872,278, filed on Aug. 30, 2013, by Siddha Pimputkar, James S. Speck and Shuji Nakamura, entitled “USE OF SUPERCRITICAL AMMONIA SOLUTIONS CONTAINING ALKALI OR ALKALI EARTH METALS TO REMOVE OXIDES FROM GROUP-III CONTAINING SOURCE MATERIALS,” attorneys' docket number 30794.528-US-P1 (2014-117-1); and

U.S. Provisional Application Ser. No. 61/872,025, filed on Aug. 30, 2013, by Siddha Pimputkar, Shuji Nakamura and James S. Speck, entitled “GROWTH OF BULK GALLIUM NITRIDE CRYSTALS IN A NON-EQUILIBRIUM GROWTH ENVIRONMENT,” attorneys' docket number 30794.530-US-P1 (2014-134-1);

both of which applications are incorporated by reference herein.

### BACKGROUND OF THE INVENTION

1. Field of the Invention

This invention relates to a method of fabricating Group-III nitride crystals and, more specifically, reactor vessels for ammonothermal and flux-based growth of Group-III nitride crystals.

2. Description of the Related Art

Bulk Group-III nitride crystal growth has been demonstrated using various methods, including the ammonothermal method, and various flux based methods, such as the high nitrogen pressure solution growth and sodium flux method. Ammonothermal growth of Group-III nitrides, for example, GaN, involves placing Group-III containing source materials, Group-III nitride seed crystals, and a nitrogen- and/or boron-containing fluid or gas, such as ammonia, into a reactor vessel, sealing the reactor, and then heating the reactor to conditions such that the reactor is at elevated temperatures (e.g., between 0° C. and 3000° C.) and high pressures (e.g., between 1 atm and 40000 atm).

Under these temperatures and pressures, the nitrogen-containing fluid becomes a supercritical fluid and normally exhibits enhanced solubility of Group-III nitride material into solution. The solubility of Group-III nitride into the nitrogen-containing fluid is dependent on the temperature, pressure and density of the fluid, among other things. By creating two different zones within the vessel, it is possible to establish a solubility gradient where in a first zone the solubility will be higher than in a second zone. The source material is then preferentially placed in the higher solubility zone and the seed crystals in the lower solubility zone. By establishing fluid motion between these two zones, for example, by making use of natural convection, it is possible to transport the Group-III containing source materials from the higher solubility zone to the lower solubility zone where it is deposited onto the Group-III nitride seed crystals.

The current state of the art includes the use of a single vessel in which the source materials and seed crystals reside. Additionally, the nitrogen-containing fluid and any additional materials that are added to the growth are enclosed in the same vessel. In doing so, it is not possible to modify the conditions within the vessel beyond removing materials or initially providing materials that become active at different stages of the process. This may be limiting if one desires, for example, to modify the concentration of certain chemicals within the vessel during growth, provide additional source material to the growth, or change the overall pressure of the reactor.

Moreover, one characteristic of these methods is that they produce superior results when operating under both high pressure and elevated temperature conditions. Therefore, in general, there is a strong motivation to design large reactors that can withstand both high pressure and elevated temperature conditions.

While this task is currently performed using steel based or nickel-chromium (Ni—Cr) based alloys, the parameter space that can be accessed in terms of both high pressure and high temperature is reaching its limits ((<4000 atm and <600° C. for Ni—Cr superalloys) or (<100 atm and <800° C. for steel based reactors)) and further improvements are desired. Additionally, limitations exist with regards to the absolute amount of scaling that can be performed for reactor designs due to size limitations in ingot size that can be produced with high enough quality for the use as autoclaves. Also, absolute limits exist for operational temperatures and pressures due to the creep strength of the metals involved. These limits have been reached in current technologies.

What is needed in the art, then, is a method and apparatus that solve these problems and provide for improved ammonothermal and flux-based growth of bulk Group-III nitride crystals. The present invention satisfies this need.

### SUMMARY OF THE INVENTION

To overcome the limitations in the prior art described above, and to overcome other limitations that will become apparent upon reading and understanding the present specification, the present invention discloses a method and apparatus for growing Group-III nitride crystals using multiple interconnected reactor vessels to modify growth conditions during the ammonothermal or flux-based growth of the Group-III nitride crystals. The present invention also discloses a method and apparatus for growing Group-III nitride crystals in a reactor vessel that uses carbon fiber containing materials encapsulating oxide ceramic materials as structural elements to contain the materials for growing the Group-III nitride crystals at pressures and/or temperatures necessary for the growth of the Group-III nitride crystals.

### BRIEF DESCRIPTION OF THE DRAWINGS

Referring now to the drawings in which like reference numbers represent corresponding parts throughout:

FIG. 1 illustrates an embodiment of the present invention where the apparatus used in the growth method includes a growth chamber connected to multiple auxiliary chambers;

FIG. 2 is a graph of Strength vs. Temperature for Common Engineering Materials;

FIG. 3 is a graph of Tensile Strength vs. Elastic Modulus showing the comparative strength properties of a single carbon fiber;

FIG. 4 is a schematic of an apparatus according to one embodiment of the present invention; and

FIG. 5 is a flowchart that illustrates a method for growing a compound crystal, such as a Group-III nitride crystal, using the apparatus of FIG. 4.

### DETAILED DESCRIPTION OF THE INVENTION

In the following description of the preferred embodiment, reference is made to the accompanying drawings which form a part hereof, and in which is shown by way of illustration a specific embodiment in which the invention may be practiced. It is to be understood that other embodiments may be utilized and structural changes may be made without departing from the scope of the present invention.

Use of Multiple Interconnected Vessels to Modify Growth Conditions

The present invention discloses the use of multiple interconnected reactor vessels to modify growth conditions for ammonothermal and/or flux-based growth of Group-III nitride crystals. By combining two or more vessels, it is possible to modify the conditions under which the Group-III nitride crystals are grown. This allows for dynamically changing the properties of the growth of the crystal without completely interrupting the growth process. Materials can be introduced or removed at any point in time.

Apparatus Description

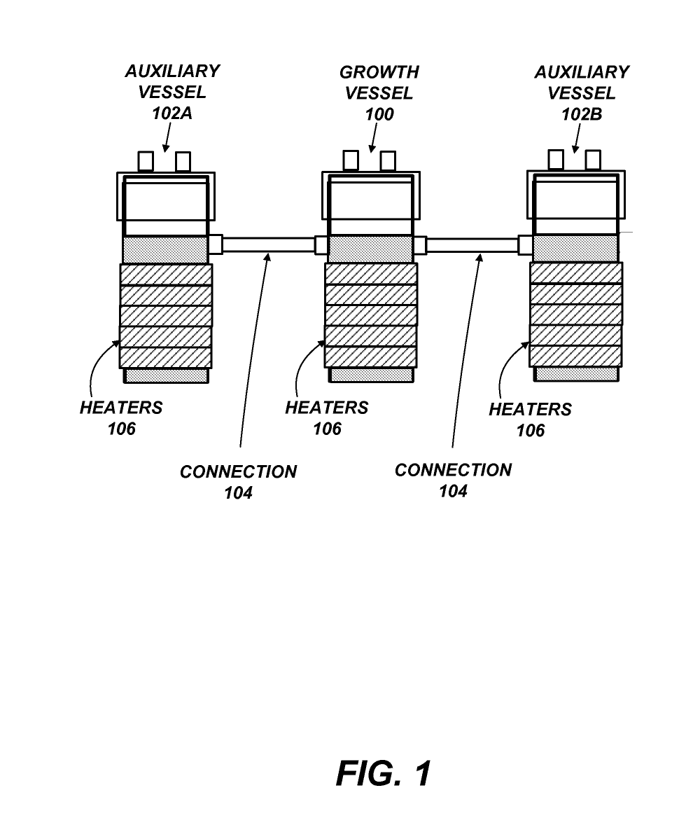

FIG. 1 is a schematic that illustrates an embodiment of the present invention where the apparatus used in the growth method includes a growth vessel 100 and one or more auxiliary vessels 102A, 102B. These multiple vessels 100, 102a, 102b are interconnected 104 and have the means to allow material to transfer between one or more of these vessels 100, 102A, 102B.

In one particular aspect of this invention, it is envisioned to have one main growth vessel 100 in which the seed crystals reside and one or more auxiliary vessels 102A, 102B which are connected 104 to the main vessel 100. These additional reactors 102A, 102B can be connected 104 to the main vessel 100 and can be initially sealed off from, or in direct connection 104 with, the main vessel 100. During growth, certain auxiliary vessels 102A, 102B may then be sealed off or opened to the growth reactor 100, thereby adding, modifying or removing material from the main growth vessel 100.

A few simple applications of this setup include the following:

1. Having one growth vessel 100 and one auxiliary vessel 102A.

Initially, the auxiliary vessel 102A is sealed with respect to the growth vessel 100. During growth, both vessels 100 and 102A may be heated 106, wherein the auxiliary vessel 102A is at a pressure higher than the growth vessel 100. A valve 104 connecting the growth vessel 100 and auxiliary vessel 102A is then opened to allow some gas from the higher pressure auxiliary vessel 102A to flow into the growth vessel 100. The additional gas from the auxiliary vessel 102A may be the same gas as already present in the growth vessel 100 (ammonia, for example), or another gas or gas mixture not present in the growth vessel 100 (nitrogen gas, for example). The end result is a finite increase in pressure and change in ratio of elements present in the growth vessel 100, with implications for the growth of the Group-III nitride crystal.

2. Having one growth vessel 100 and one auxiliary vessel 102A, wherein the auxiliary vessel 102A contains a chemical not present within the growth vessel 100, for example, sodium metal. The auxiliary vessel 102A may be subject to multiple processes prior to engaging the connection 104 to the growth vessel 100. The processes subjected to the auxiliary vessel 102A may include purifying steps to provide higher purity materials, for example, source material or additives such as mineralizers. Once the auxiliary vessel 102A is connected 104 to the growth vessel 100, the connection valve 104 may be opened during or before growth, allowing some of the fluids within the growth vessel 100 to transfer into or out of the auxiliary vessel 102A. In doing so, the fluids may react with the materials within the auxiliary vessel 102A, thereby changing the chemical composition of the fluid. This, in turn, may modify the growth and quality of the Group-III nitride crystals.

3. Having one growth vessel 100 and multiple auxiliary vessels 102A, 102B. During a long growth run, it is possible that the total pressure in the growth vessel 100 will drop, for example, due to diffusion of hydrogen out of the reactor 100. This mass loss can be addressed by opening the valve 104 to one of the auxiliary vessels 102A, thereby replenishing the amount of, for example, hydrogen. For very long growth runs, connections 104 from multiple auxiliary vessels 102A, 102B may be opened sequentially, providing the measures to perform longer uninterrupted growth runs.

4. Having one growth vessel 100 and multiple auxiliary vessels 102A, 102B, it is possible to subject the growth vessel 100 to multiple cleaning cycles or growth modifications by incrementally connecting 104 the contents of one auxiliary vessel 102A or 102B to the growth vessel 100 and after each connection 104, release or vent the gas. In doing so, it is possible to purify the system by removing undesired materials and additionally modify the chemistry of the growth by adding different chemical gases and source material. For example, if one desires to grow a Group-III nitride crystal doped with a large amount of one type of element, for example, silicon, and then a layer of Group-III nitride crystal doped with a large amount of another type of element, for example, magnesium, it is possible to do so within the same growth. This can be achieved, for example, by having two auxiliary vessels 102A, 102B connected 104 to the main growth vessel 100. The first auxiliary vessel 102A contains, among other materials, silicon. This silicon can then be transported into the growth vessel 100 during growth via connection 104. Once the growth of the silicon doped crystal is complete, the connection 104 from the first auxiliary vessel 102A with the silicon is sealed off from the growth vessel 100, the contents of the growth vessel 100 are removed and the second auxiliary vessel 102B is made available to the growth vessel 100 via connection 104. This second auxiliary vessel 102B contains, among other things, for example, magnesium. This magnesium can in turn then be consumed and used in the growth of Group-III nitride crystal.

5. Having one growth vessel 100 and at least one auxiliary vessel 102A, 102B, it is possible to setup a potential difference between the growth vessel 100 and auxiliary vessel(s) 102A, 102B. In doing so, it is possible to modify the chemical potential of various species within all vessels 100, 102A, 102B, thereby modifying the growth environment. Additionally, it may be possible to configure the system such that the auxiliary vessel 102A, 102B acts as a sink for undesired chemical products or materials from the growth vessel 100.

6. Having one growth vessel 100 and at least one auxiliary vessel 102A, 102B, it is even possible to physically separate the source materials zone from the seed zone, by having the source materials zone in an auxiliary vessel 102A, 102B, and the seed zone in the growth vessel 100. In doing so, it is possible to have most, if not all, of the growth vessel 100 filled with Group-III nitride seed crystals, and one or more auxiliary vessels 102A, 102B, which are filled with Group-III containing source materials that will provide, at least in part, the materials needed for the growth of Group-III nitride crystals. The advantages of separating the growth vessel 100 from the auxiliary vessels 102A, 102B are plentiful. The temperatures for the source materials zone and the seed zone can be easily and uniformly achieved using the heaters 106. Internal convection within the seed zone and source materials zone are now largely independent and can be individually regulated to achieve optimal performance for each process. Furthermore, in order to ensure optimal concentrations of Group-III materials within the source materials zone and seed zone, it is possible to have multiple auxiliary vessels 102A, 102B which contain Group-III materials. In doing so, the dissolution rate can be effectively increased by having multiple processes occurring in parallel. The individual auxiliary vessels 102A, 102B can then be connected 104 in parallel or sequentially to the growth vessel 100 providing the necessary materials for the growth of the crystals.

7. In lieu of example #6 above, it is further possible to envision the use of a multi-vessel setup in which the growth vessel 100 and source material containing vessel(s) 102A, 102B are synchronized in such a fashion that the following processes can be achieved: source material containing vessel 102A is filled with a solvent that allows for the dissolution of the source materials. Once saturated with Group-III containing materials, the fluid is allowed to enter the growth vessel 100, which contains the seed crystals, via connection 104. The temperature of the growth vessel 100 is set using the heater 106 such that the Group-III containing materials deposit themselves on the seed crystal and growth. After significantly depleting the fluid of Group-III containing source materials, the fluid is removed from the growth vessel 100, potentially to an exhaust line. The source materials containing vessel 102A has since been replenished with new solvent and has been saturated in Group-III containing source materials. This fluid is then allowed to enter the growth vessel 100 via connection 104 for a renewed cycle of growth. This process can be repeated multiple times. Furthermore, in the current example, only one source material containing vessel 102A was mentioned. It is possible to envision multiple source material containing vessels 102A, 102B connected 104 to the growth vessel 100 and allowed, sequentially, to fill the growth vessel 100 and allow for the growth of the Group-III nitride crystals.

The method used to connect 104 the various vessels 100, 102A, 102B should not be considered limiting. These connections 104 may include, but are not limited to, simple tubes and manual valves, or in more sophisticated setups, for example, the use of pumps, flow management equipment, line heaters, etc. Additionally, the connections 104 between the various vessels 100, 102A, 102B need not be direct, but may be through other equipment, for example, some of the fluid is passed through a mass spectrometer to determine the chemical composition, or the fluid is analyzed in an intermediate chamber in which, for example, other scientific techniques can be used to achieve the desired results, or provide feedback on the state of the chemicals within the fluids which is being transported.

It is possible to connect 104 all vessels 102A, 102B to one main vessel 100, or multiple vessels 100, 102A, 102B may be interconnected 104 to allow mass transfer between the multiple vessels 100, 102A, 102B directly and simultaneously. Additionally, the conditions within each separate vessel 100, 102A, 102B may be controlled independently. This may manifest itself through the means of independent temperature control of the heaters 106.

Use of Ceramics and Composite Materials for the Growth of Group-III Nitride Bulk Crystals

As noted above, the growth of Group-III nitride crystals is challenging due to the high growth temperatures required and the need for a high nitrogen overpressure, as without it, GaN would decompose into Ga and N₂ gas. In order to grow bulk GaN crystals, it is therefore necessary to find a suitable growth method that overcomes these challenges and allows for the continuous growth using a Ga and N source.

Current technology utilizes metal-based autoclave designs when growing using the ammonothermal method and Na-flux based methods. The methods differ in that, in the ammonothermal method, Ga is dissolved into a supercritical ammonia solution and is then deposited onto the growing GaN crystal. The Na-flux based method uses a flux containing Na and Ga, and nitrogen is provided as gas with sufficient overpressure, such that it dissolves into the flux and deposits itself onto the seed crystal, thereby increasing the size of the crystal. Various different fluxes exist, although they all are subject to the same concept of dissolution of nitrogen into the flux and transport to the crystal surface.

It has been generally observed that it is beneficial to use higher temperatures for growth as this provides higher kinetic energy for the various reactions to occur. Furthermore, with higher temperatures, the need for higher pressures becomes more important as GaN would otherwise decompose. This combination of two factors yields a system in which higher temperatures and higher pressures are desired for improved, faster growth of high quality, high purity bulk GaN single crystals.

Traditional chambers used for the growth of these crystals make use of steels or Ni—Cr super alloys. Current applications of these reactor designs have been pushed to the limits in which these materials can operate effectively. To further improve on the growth of Group-III nitride crystals, it is desirable to obtain even higher pressures at elevated operating temperatures.

The present invention encapsulates oxide ceramic materials in carbon fiber containing materials to further expand the design space in which reactor vessels can be built. Moreover, not only is the combination strong, it can be easily scaled and can operate at higher temperatures and pressures. The present invention results in the production of bulk Group-III nitrides at significantly lower cost, higher throughput, greater growth rate, higher quality, higher purity and transparency.

Apparatus Description

The present invention makes use of carbon fiber containing materials, such as carbon-carbon-fiber composites (CCFC) materials, to encapsulate oxide ceramic materials in the construction of reactor vessels for compound crystals. Using this combination of materials, it is possible to reduce the diffusion of materials out of the vessel, as well as design large scale reactor vessels that can withstand both the high pressures and elevated temperatures that are necessary for the growth of Group-III nitride crystals.

This is in part due to the exceptionally high strength of the bonds in the direction of the carbon fiber. Generally speaking, common grade steels have tensile strengths of 500-1000 MPa at temperatures below ˜600° C., and ultra high strength steels have tensile strengths of up to 3500 MPa at room temperatures, while carbon fibers have tensile strengths of ˜6000 MPa at temperatures up to at least 2000° C. Carbon fiber composites actually become stronger as temperatures increase.

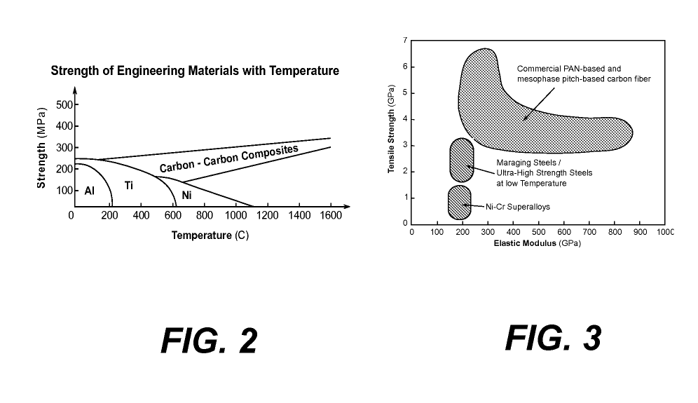

This is reflected in FIG. 2, which is a graph of Strength (MPa) vs. Temperature (C) for common engineering materials including Aluminum (Al), Titanium (Ti), Nickel (Ni) as compared to Carbon-Carbon Composites, and FIG. 3, which is a graph of Tensile Strength (GPa) vs. Elastic Modulus (GPa) showing the comparative strength properties of Ni—Cr superalloys, maraging steels or ultra-high strength steels at low temperature, and commercial polyacrylonitrile (PAN) based and mesophase pitch-based carbon fiber.

While the structural properties of carbon fibers are highly directional, and hence anisotropic, it is possible to arrange the fibers in appropriate weaving patterns to obtain a well engineered product to absorb any applicable stresses along any desired direction. Further engineering also allows material to be created that has a coefficient of thermal expansion that is smaller than that of material it is encapsulating. This may have considerable impact for high temperature applications, as a significant amount, if not all, of the stresses can be transferred from a ceramic material to the carbon fiber composite when the carbon fiber based material has been wrapped around the ceramic material, thereby further extending the pressure and temperature range in which the reactor can safely operate.

The present invention claims the use, however minimal, of any carbon fiber containing materials encapsulating oxide ceramic materials in the design of a reactor vessel for the growth of compound crystals. Carbon fiber containing materials, most notably carbon fiber composites, such as carbon fiber-carbon, carbon fiber-epoxy, carbon fiber-polymer, carbon fiber-ceramic, and carbon fiber-metal composites, are used to encapsulate the oxide ceramic materials, and the combination is used to contain and generate materials under high temperature and high pressure volumes within a closed space that are, in turn, used, at least partially and in some part of the process, to generate compound crystals.

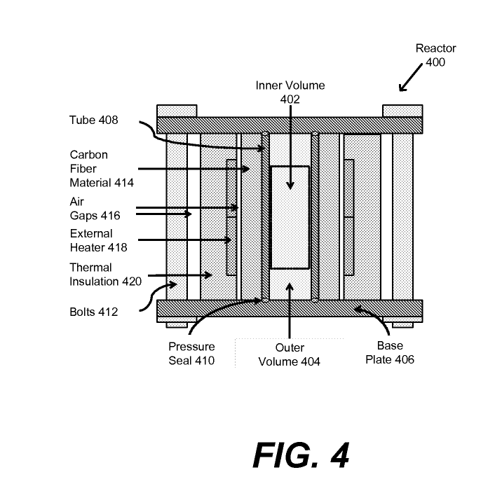

FIG. 4 is a schematic of an apparatus for growing Group-III nitride crystals according to one embodiment of the present invention, comprising a reactor vessel including at least one volume for containing materials for growing the Group-III nitride crystals using an ammonothermal or flux-based growth method, wherein the reactor vessel uses carbon fiber containing materials encapsulating oxide ceramic materials as structural elements to contain the Group-III nitride growth materials as a solid, liquid or gas within the volume, such that the reactor vessel can withstand pressures or temperatures necessary for the growth of the compound crystals, for example, where the pressures range from about 1 atm to about 40000 atm and the temperatures range from about 20° C. to about 3000° C.

Specifically, the reactor 400 includes one or more nested vessels labeled as inner volume 402 and outer volume 402, either or both of which may be sealed or open. The inner volume 402 may be a tube, cylinder, sleeve or capsule, and is fully contained within the outer volume 404, which also may be a tube, cylinder, sleeve or capsule.

Either or both of the vessels may be considered as crucible for the growth of compound crystals, such as Group-III nitride crystals, which are grown using Group-III containing source materials, Group-III nitride seeds and a nitrogen-containing solvent. Generally, the inner volume 402 and outer volume 404 together are used to perform one or more methods of growing Group-III nitride crystals, wherein the method may comprise a flux based method including a sodium flux based method, a high nitrogen pressure solution growth based method, or an ammonothermal method.

Preferably, either or both of the vessels may operate at the wide pressure and temperature ranges described above. Both or either the inner volume 402 and the outer volume 404 may be comprised of one or more materials that are capable of withstanding ultra-high pressure and temperature, such as metals, ceramics, polymers, carbon fiber such as a carbon fiber based composite, or any combination thereof.

The structure of the outer volume 404 is defined by high strength top and bottom plates 406, a tube 408 of hermetic material, and hermetic high pressure seals 410, wherein the plates 406 are coupled together by ultra high strength bolts 412. A load bearing carbon fiber containing material 414, such as a graphite fiber containing material 414, is positioned on the outer side of the sidewalls of the tube 408, and a first air gap 416 separates the carbon fiber material 414 from external heaters 418. Thermal insulation 420 is positioned on the outer side of the external heaters 418, and a second air gap 416 separates the thermal insulation 420 from the bolts 412.

Specifically, the outer volume 404 is created by sandwiching the tube 408 comprised of the hermetic material, which may be made of a ceramic, in between the two plates 406, which also may be made of a ceramic, a metal, a carbon fiber containing material, or any combination thereof, such that the oxide ceramic materials are placed between the inner volume 402 of the reactor vessel 400 and the carbon fiber containing materials 414. Compression along the center line of the tube 408 is achieved by tightening the bolts 412 around the perimeter of the two plates 406. Through engineering, it is possible to provide a hermetic seal 410 between the tube 408 and the two plates 406 at both ends of the tube 408. This, in effect, provides a hermetically sealed outer volume 404 in which any gas, liquid or solid may be placed.

The apparatus of FIG. 4 is based upon a similar design previously described by the inventors in the cross-referenced U.S. Utility patent application Ser. No. 13/860,382, filed on Apr. 10, 2013, 2012, by Siddha Pimputkar, Paul Von Dollen, Shuji Nakamura, and James S. Speck, and entitled “APPARATUS USED FOR THE GROWTH OF GROUP-III NITRIDE CRYSTALS UTILIZING CARBON FIBER CONTAINING MATERIALS AND GROUP-III NITRIDE GROWN THEREWITH,” attorneys' docket number 30794.451-US-U1 (2012-654-2), which application claims the benefit under 35 U.S.C. Section 119(e) of U.S. Provisional Patent Application Ser. No. 61/622,232, filed on Apr. 10, 2012, by Siddha Pimputkar, Paul Von Dollen, Shuji Nakamura, and James S. Speck, and entitled “APPARATUS USED FOR THE GROWTH OF GROUP-III NITRIDE CRYSTALS UTIILIZING CARBON FIBER CONTAINING MATERIALS AND GROUP-III NITRIDE GROWN THEREWITH,” attorneys' docket number 30794.451-US-P1 (2012-654-1), both of which applications are incorporated by reference herein.

This previous design used a composite material to function as a structural unit 414 of the reactor 400 to contain the high pressures involved at high temperatures. The use of CCFC has the potential of significantly expanding on the existing rector technology allow for the accessing of parameter space previously only accessible using costly experimental setups. However, the tube 408 in the previous version of the apparatus of FIG. 4 was comprised of a metal.

The present invention improves on the design of a CCFC reactor 400. One of the challenges when going to higher temperatures and pressures is that the structural integrity of the material around which the CCFC is wrapped may reduce in integrity and soften. Furthermore, given the higher temperatures, the diffusion of various chemical species is enhanced, including those making up the material around which the CCFC is wrapped. High pressures increase the driving force for material to diffuse out of the high-pressure system. Hydrogen is especially problematic as it is such a light material and readily diffuses through metals at high temperatures.

All these problems present significant hurdles in the implementation of a functioning CCFC reactor. The present invention discloses the use of a ceramic material for the tube 408, which effectively eliminates the above-mentioned problems. More specifically, the tube 408 may comprise an oxide ceramic.

In one embodiment, the oxide ceramic materials of the tube 408 comprise alumina (Al₂O₃), although other ceramics may be used as well. Moreover, the oxide ceramic materials may be present in a micro-structure, including a single crystal alumina, alumina in SiO₂, or mixtures of various different types of oxide ceramics containing Al or Si. In addition, the oxide ceramic material may be a single crystal, a sintered material, or an amorphous material, including glasses. Alternatively, the oxide ceramic materials may be deposited onto a shell of another material, such as a metal or another ceramic.

The oxide ceramic tube 408 is wrapped on the outside by the carbon fiber containing material 414. As a result, the carbon fiber containing materials 414 encapsulate at least one component of the reactor vessel 400, wherein stresses from the encapsulated component are transferred to the carbon fiber containing materials 414. Moreover, the carbon fiber containing materials 414 may be wrapped around the oxide ceramic tube 408 one or more times sufficient to maintain a desired pressure differential between an exterior and interior of the oxide ceramic tube 408, e.g., to maintain a pressure differential across the exterior of the tube 408 and the interior of the tube 408. In its most basic form, this invention includes the application of the carbon fiber containing composite materials 414 and the oxide ceramic tube 408 to contain a solid, liquid, gas, and/or supercritical fluid in the closed space of the outer volume 404 and inner volume 402 at elevated pressures and temperatures.

Ceramics are a class of materials which are structurally stable to exceedingly high temperatures. They form covalent/ionic bonds with neighboring atoms allowing for exceedingly high yield strengths. The challenge with ceramics is that, under tension, they typically fail through the formation of cracks, as they are not ductile. Under compression, though, they exhibit exceedingly high yield strengths when compared to metals and are therefore typically used in these situations, especially when subject to high temperatures.

In addition to their good structural properties in compression, they are typically chemically stable even at high temperatures. This comes from the fact that most ceramics, chemically speaking, are very stable.

Furthermore, given their strong bonds, diffusion within ceramics is typically only possible at elevated temperatures, markedly higher than those for metals. This is advantageous, as when a reactor 400 comprising CCFC is used in junction with a vessel that contains hydrogen at elevated temperatures and pressure. The hydrogen will have a tendency to diffuse out of the high pressure volume given the increased thermal energy available as it is at high temperature and high pressure providing a large driving force for outward diffusion. This situation can be present during the growth of bulk GaN crystals using the ammonothermal method. Outward diffusion of hydrogen during growth at 600° C. is already pronounced and at 1000° C. becomes significantly worse.

Ceramics can be selected for use in the tube 408 that have low permeability of hydrogen at such growth temperatures. Alumina, Al₂O₃, is one example of a ceramic that was found to be suitable for the tube 408 as it is structurally sound and available in single crystal form, along with having a hydrogen permeability constant which is 104 times lower at 1000° C. than for Ni—Cr superalloys typically used for the construction of ammonothermal autoclaves. (See references [1] and [2] set forth below.)

Another motivation, besides reducing mass loss of hydrogen from the growth system, is the possibility of hydrogen reacting with the CCFC material. Hydrogen can form methane when exposed to carbon-containing material. This is a problem as long-term exposure can lead to etching of the structural material and unexpected failure can occur. It is therefore desirable to reduce the exposure of hydrogen to the CCFC material. This can be done by removing the hydrogen gases before it reaches the CCFC material, or by significantly reducing the amount of hydrogen that can diffuse to the CCFC material. Utilizing, for example, a layer of alumina material as the tube 408 placed between the high pressure volume and the CCFC material, this can be readily achieved given the significant resistance hydrogen sees while diffusing through this material.

Given the stability of the alumina system to a flux containing Na and Ga, it is further desirable to use alumina as a vessel material as it is chemically stable to the chemistry present during the growth of GaN using the Na-flux method. This reduces potential undesirable reactions of the highly reactive gallium and sodium metal with other metals making up the inner most layer being exposed to the growth environment.

It is important to note that the ceramic material does not necessarily need to be the only material present in addition to the CCFC material, but can be one of many layers.

Also, given the changes in thermal expansion of the CCFC and elastic moduli, the alumina material should remain in compression during a run, thereby eliminating the concern of crack formation. The compressive properties of the ceramic become more relevant.

### ALTERNATIVES AND MODIFICATIONS

The following describes some possible alternatives and modifications that may be made to the present invention.

For example, the carbon fibers in the carbon fiber containing material 414 may be long or short, and continuous or discontinuous. The carbon fibers may be embedded in a matrix. Moreover, the carbon fibers may be weaved or otherwise arranged in such a fashion that a multitude of the strands may run at one or more angles with respect to other strands in order to provide additional strength in carbon fiber containing material 414.

In one example, the carbon fiber containing material 414 comprises a carbon fiber composite, selected from a group comprised of carbon fiber-carbon, carbon fiber-epoxy, carbon fiber-polymer, carbon fiber-ceramic, and carbon fiber-metal composites.

The carbon fiber containing material 414 may be wrapped around another material, such as a carbon fiber containing material, a metal containing material, a ceramic containing material, or any combination thereof.

One or more layers of additional material may coat the carbon fiber containing material 414 or the encapsulated component. For example, it possible that the exterior and/or interior of either or both the inner volume 402 and outer volume 404 may be coated with one or more layers of additional material. Additionally, the tube 408 may be comprised of a single tube, or multiple tubes nested within each other, to tailor towards particular physical or chemical properties.

Specifically, these layers of additional material may comprise interior or exterior liner materials that are used to protect the various components, namely, the carbon fiber containing material 414, the exterior of the tube 408, the interior of the outer volume 404, and both the interior and exterior of the inner volume 402. The layers of additional material may be used to: (1) protect the carbon fiber containing material 414 or the encapsulated component, (2) improve on the ability of the carbon fiber containing material 414 or the encapsulated component to maintain a certain pressure or temperature, (3) make the carbon fiber containing material 414 or the encapsulated component chemically resistant to any materials that are placed in contact with the carbon fiber containing material 414 or the encapsulated component, (4) improve on an amount of impurities that are present within the reactor vessel 400 (e.g., preventing contaminates from being incorporated into the inner volume 402 or the outer volume 404), (5) remove matter from the reactor vessel 400 (e.g., removing oxygen from the inner volume 402 or the outer volume 404 using a titanium coating that reacts with oxygen forming titanium dioxide), or (6) reduce hydrogen diffusion out of the inner volume 402 and/or the outer volume 404 by utilizing at least one material with a low permeability of hydrogen under operating conditions. Examples of layers of additional material may include coatings with a noble metal, such as gold, silver, platinum, iridium, palladium, etc., although other materials may also be used, including non-metals, such as ceramics or glasses.

One or more additional elements may be present in the reactor vessel 400, allowing for matter, charged particles, photons, electric fields, or magnetic fields to travel into or out of the reactor vessel 400. For example, the additional elements may comprise electrically conductive wires, optically transparent materials, tubes, or magnetic materials.

After wrapping the tube 408 with the carbon fiber containing material 414, the heaters 418 are then placed outside the carbon fiber containing material 414. These heaters 418 do not need to, nor necessarily should, touch the carbon fiber containing material 414 and there can be an air gap 416 between the heaters 418 and the carbon fiber containing material 414. The heaters 418 can then be used to heat the outer volume 404 and inner volume 402, thereby increasing the pressure and creating an environment suitable for the growth of a Group-III nitride crystals, such as GaN.

The external heaters 418 may be present as separate units external to the carbon fiber containing material 414, but may also be incorporated, at least partially or fully, into the carbon fiber containing material 414 itself, or use the carbon fiber containing material 414 itself as the heater. This combination would allow the carbon fiber containing material 414 to additionally act as a heating source, thereby eliminating the need for a separate heater 418. Moreover, the carbon fiber containing material 414 maybe used as a heat sink as well as a heat source.

As the outer volume 404 is hermetically sealed, it is possible to achieve appreciable pressures at appreciable temperatures as the ultra high strength bolts 412 can safely retain the force exerted by the pressure on the two plates 406 capping the tube 408. Given that thermal insulation materials 420 can be placed between the heaters 418 and the bolts 412, the temperature of the bolts 412 can be very low, well below temperatures under which the bolts 412 will lose any appreciable strength, leading to creep. The hoop stresses can be transferred from the tube 408 to the overwrapped carbon fiber containing materials 414. Given the stiffness and strength of the carbon fiber containing material 414, the fibers will provide the necessary strength to prevent any expansion of the tube 408 and prevent creeping and ultimate failure of the tube 408. As carbon fibers do not lose strength at increased temperatures (quite the contrary, they become stronger as the temperature increases), the carbon fiber containing material 414 will not creep and hence cause catastrophic failure and rupture of the tube 408.

Although this embodiment described herein uses multiple nested vessels, namely inner volume 402 and outer volume 404, wherein the inner volume 402 is completely surrounded by or nested within the larger sized outer volume 404, other embodiment may use more than two nested vessels or only a single vessel. Also, while the embodiment described herein only describes the use of one structure combining carbon fiber based materials 414 encapsulating the oxide ceramic tube 408 to retain significant stresses generated by elevated pressures, multiple such structures may be used as well, for example, each of the volumes 402, 404 may use such a carbon fiber containing material 414 encapsulating the oxide ceramic tube 408.

Note that this example, which should not been seen to be limiting in any way, is provided to demonstrate one possible application of this invention towards the ammonothermal growth of GaN.

One alternative embodiment, as applied to the sodium flux method, would include a larger outer vessel which is designed using carbon fiber containing materials encapsulating oxide ceramic to retain significant pressures. Within this large outer vessel, one places insulation material, heaters and a smaller inner vessel which is also designed using carbon fiber containing materials encapsulating oxide ceramic to retain significant pressures. The insulation material can be used to isolate the heaters from the carbon fiber based elements of the larger outer vessel to ensure that a certain critical temperatures are not exceeded. The heaters, in turn, are designed to heat the smaller inner vessel. A Group-III nitride crystal is then grown within the smaller inner vessel, wherein the smaller inner vessel may or may not be at the same pressure as the pressure retained by the larger outer vessel. The benefits of this design allows one: (i) to obtain an absolute pressure within the smaller inner vessel at significantly higher pressures than would be possible if only the larger outer vessel were used and (ii) to decouple the pressure containing materials from the temperature exposed materials.

One motivation to use internal heating and using methods to reduce the experienced temperature at the carbon fiber containing material is that carbon fiber composite may be used that are preferable for lower temperature applications. One such composite includes the use of carbon fiber-polymer matrix (for example, a carbon fiber-epoxy composite) which is currently used for hydrogen storage tanks at room temperature.

While it is possible to make use of internal heating as described in the previous paragraphs, this is not necessary, as one of the strengths of carbon fiber containing materials is that they retain their strength at extreme temperatures. This leads to the possibility of externally heating the carbon fiber encapsulated volume and arranging any number of elements within the chamber to one's desires to achieve the best possible growth of Group-III nitride crystals. The suitable environment for growth may include an ammonia, nitrogen, and hydrogen-containing environment. One or more vessel or containers may exist within the carbon fiber encapsulated volume to hold a liquid, such as molten metals.

Ammonothermal or Flux-Based Process

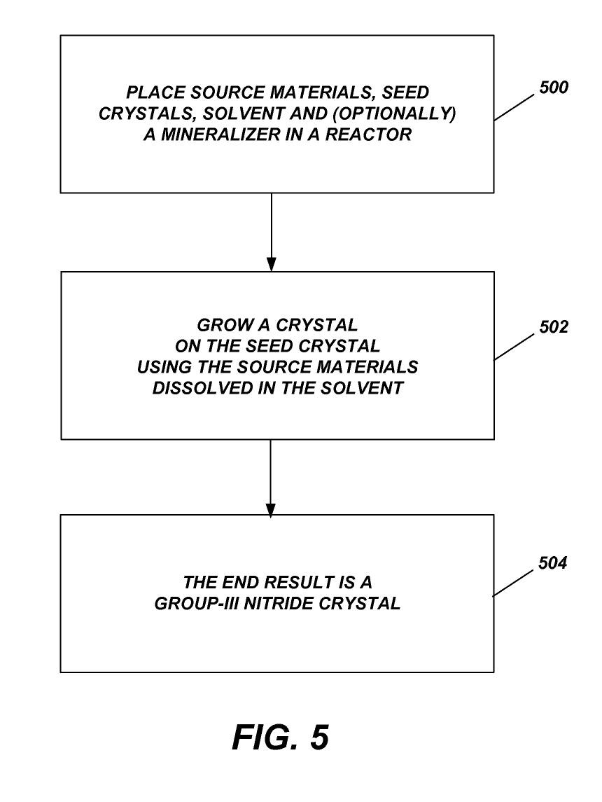

FIG. 5 is a flow chart illustrating a method for obtaining or growing a Group-III nitride-containing crystal using the apparatus of FIG. 1 and/or FIG. 4 according to one embodiment of the present invention.

Block 500 represents placing one or more Group-III nitride seed crystals, one or more Group-III containing source materials, and a nitrogen-containing solvent in the vessels, wherein the seed crystals are placed in a seed zone, the source materials are placed in a source materials zone. The seed crystals comprise a Group-III containing crystal; the source materials comprise a Group-III containing compound, a Group-III element in its pure elemental form, or a mixture thereof, i.e., a Group-III nitride monocrystal, a Group-III nitride polycrystal, a Group-III nitride powder, Group-III nitride granules, or other Group-III containing compound; and the solvent comprises supercritical ammonia or one or more of its derivatives, which may be entirely or partially in a supercritical state. An optional mineralizer may be placed in the vessels as well, wherein the mineralizer increases the solubility of the source materials in the solvent as compared to the solvent without the mineralizer. The zones may be located in a single vessel, nested vessels, or separate interconnected vessels, as described above.

Block 502 represents growing Group-III nitride crystal on one or more surfaces of the seed crystals, wherein the environments and/or conditions for growth include forming a temperature gradient between the seed zone and the source materials zone that causes a higher solubility of the source materials in the solvent in the source materials zone and a lower solubility, as compared to the higher solubility, of the source materials in the solvent in the seed zone. Specifically, growing the Group-III nitride crystals on one or more surfaces of the seed crystals occurs by changing the source materials zone temperatures and the seed zone temperatures to create a temperature gradient between the source materials zone and the seed zone that produces a higher solubility of the source materials in the solvent in the source materials zone as compared to the seed zone. For example, the source materials zone and seed zone temperatures may range between approximately 0° C. and 3000° C., and the temperature gradients may range between approximately 0° C. and 3000° C. Moreover, the reactor vessels may maintain high pressures between approximately 1 and 40000 atm.

Block 504 comprises the resulting product created by the process, namely, one or more Group-III nitride crystals grown on the seed crystals. The Group-III nitride crystals are characterized as AlₓB_{y}Ga_{z}In_{(1-x-y-z)}N, where 0<=x<=1, 0<=y<=1, 0<=z<=1, and x+y+z<=1. For example, the Group-III nitride crystals may be AlN, GaN, InN, AlGaN, AlInN, InGaN, etc. A Group-III nitride substrate may be created from a Group-III nitride crystal, and a device may be created using the Group-III nitride substrate.

### REFERENCES

The following references are incorporated by reference herein.
[1] A. D. Le Claire, “Permeation of Gases Through Solids/III—An Assessment of Measurements of the Steady State Permeability of H and Its Isotopes Through Ni and Through Several High Ni Commercial Alloys and Steel,” AERE-R 10846, Materials Development Division, AERE Harwell (March 1983).
[2] E. Serra et al., “Hydrogen Permeation Measurements on Alumina,” J. Am. Ceram. Soc., 88 [1] 15-18 (2005).

### NOMENCLATURE

The terms “Group-III nitride” or “III-nitride” or “nitride” as used herein refer to any composition or material related to (Al,B,Ga,In)N semiconductors having the formula Al_{w}BₓGa_{y}In_{z}N where 0<w<1, 0<x<1, 0<y<1, 0<z<1, and w+x+y+z=1. These terms as used herein are intended to be broadly construed to include respective nitrides of the single species, Al, B, Ga, and In, as well as binary, ternary and quaternary compositions of such Group III metal species. Accordingly, these terms include, but are not limited to, the compounds of AlN, GaN, InN, AlGaN, AlInN, InGaN, and AlGaInN. When two or more of the (Al,B,Ga,In)N component species are present, all possible compositions, including stoichiometric proportions as well as off-stoichiometric proportions (with respect to the relative mole fractions present of each of the (Al,B,Ga,In)N component species that are present in the composition), can be employed within the broad scope of this invention. Further, compositions and materials within the scope of the invention may further include quantities of dopants and/or other impurity materials and/or other inclusional materials.

### CONCLUSION

This concludes the description of the preferred embodiment of the present invention. The foregoing description of one or more embodiments of the invention has been presented for the purposes of illustration and description. It is not intended to be exhaustive or to limit the invention to the precise form disclosed. Many modifications and variations are possible in light of the above teaching. It is intended that the scope of the invention be limited not by this detailed description, but rather by the claims appended hereto.

What is claimed is:

1. An apparatus used for the growth of Group-III nitride crystals, comprising:
(a) two or more vessels that are interconnected, wherein Group-III source materials are placed into one or more of the vessels and Group-III seed crystals are placed into one or more of the vessels; and
(b) means for regulating mass flow between the two or more vessels, such that one or more of the vessels is filled with a fluid for dissolving the Group-III source materials and transporting the dissolved Group-III source materials to the Group-III seed crystals for ammonothermal or flux-based growth of the Group-III nitride crystals.

2. The apparatus of claim 1, wherein at least one of the vessels is used to prepare the Group-III source materials for future introduction into at least another one of the vessels containing the Group-III seed crystals.

3. The apparatus of claim 1, wherein at least one of the vessels is at a higher pressure than at least another one of the vessels.

4. The apparatus of claim 1, wherein connections between the vessels allow materials to be transported within the connections between the vessels without exposing the materials to an environment outside the vessels.

5. The apparatus of claim 1, wherein at least one of the vessels is filled with materials from an external source while at least one of the other vessels is in operation.

6. The apparatus of claim 5, wherein at least one of the vessels is disconnected from at least another one of the vessels, opened, filled with materials, sealed, and reconnected.

7. The apparatus of claim 1, wherein at least one of the vessels is used to purify materials involved in the growth of the Group-III nitride crystal.

8. The apparatus of claim 1, wherein at least one of the vessels has means for removing material to an external environment.

9. The apparatus of claim 1, wherein at least one of the vessels includes one or more gas tanks containing pressured gases and/or liquids.

10. The apparatus of claim 1, wherein at least one of the vessels is at a different potential than at least another one of the vessels.

11. The apparatus of claim 1, wherein the vessels and/or connections are heated.

12. A method for growing Group-III nitride crystals, comprising:
(a) interconnecting two or more vessels, wherein Group-III source materials are placed into one or more of the vessels and Group-III seed crystals are placed into one or more of the vessels;
(b) regulating mass flow between the two or more vessels, such that one or more of the vessels is filled with a fluid for dissolving the Group-III source materials and transporting the dissolved Group-III source materials to the Group-III seed crystals for ammonothermal or flux-based growth of the Group-III nitride crystals.

13. An apparatus for growing Group-III nitride crystals, comprising:
(a) a reactor vessel including at least one volume for containing materials for growing the Group-III nitride crystals using an ammonothermal or flux-based growth method;
(b) wherein the reactor vessel uses carbon fiber containing materials encapsulating oxide ceramic materials as structural elements to contain the materials for growing the Group-III nitride crystals at pressures or temperatures necessary for growth of the Group-III nitride crystals.

14. The apparatus of claim 13, wherein the oxide ceramic materials comprise alumina (Al₂O₃), alumina in SiO₂, or mixtures of various different types of oxide containing Al or Si.

15. The apparatus of claim 13, wherein the oxide ceramic materials are a single crystal, a sintered material, or an amorphous material.

16. The apparatus of claim 13, wherein the oxide ceramic materials are deposited onto another material.

17. The apparatus of claim 13, wherein the oxide ceramic materials are placed between an inner volume of the vessel and the carbon fiber containing materials.

18. The apparatus of claim 13, wherein the oxide ceramic materials are in direct contact with the carbon fiber containing materials.

19. The apparatus of claim 13, wherein the carbon fiber containing materials are wrapped around a tube or other structure formed from the oxide ceramic materials one or more times sufficient to maintain a desired pressure differential between an exterior and interior of the oxide ceramic materials.

20. A method for growing Group-III nitride crystals, comprising:
(a) growing the Group-III nitride crystals in a reactor vessel including at least one volume for containing materials for growing the Group-III nitride crystals using an ammonothermal or flux-based growth method;
(b) wherein the reactor vessel uses carbon fiber containing materials encapsulating oxide ceramic materials as structural elements to contain the materials for growing the Group-III nitride crystals at pressures or temperatures necessary for growth of the Group-III nitride crystals.
